(19) United States
(12) Patent Application Publication
(10) Pub. No.: US 2006/0180807 A1
(43) Pub. Date: Aug. 17, 2006

(54) Electroluminescent device with homogeneous brightness

(75) Inventors: Hans-Helmut Bechtel, Roetgen (DE); Dietrich Bertram, Aachen (DE)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS N.V., EINDHOVEN (NL)

(21) Appl. No.: 10/564,658

(22) PCT Filed: Jul. 5, 2004
(86) PCT No.: PCT/IB04/51115

§ 371 Date: Jan. 13, 2006

(30) Foreign Application Priority Data
Jul. 16, 2003 (EP) 03102176.9

(51) Int. Cl. H01L 29/08

(52) U.S. Cl. 257/40

(57) ABSTRACT

The invention describes an electroluminescent device equipped with a substrate, a metallic structure and a layer assembly comprising at least a first electrode, an electroluminescent layer and a second electrode. The metallic structure, which is in electrical contact with the first electrode, exhibits a lower layer resistance than the first electrode. Owing to the electrical contact with the first electrode, the layer resistance of the first electrode, and thus the voltage drop over the first electrode, is reduced.

The invention relates to an electroluminescent device equipped with a substrate and a layer assembly comprising at least a first electrode, an electroluminescent layer and a second electrode.

Electronically triggered display systems are known, and widely encountered, in various embodiments based on various principles.

One principle uses organic light-emitting diodes, known as OLEDs, as the light source. Organic light-emitting diodes are constructed from multiple functional layers. A typical structure of an OLED is described in “Philips Journal of Research, 1998, 51, 467”. A typical structure comprises a layer of ITO (Indium Tin Oxide) as the transparent electrode (anode), a conductive polymer layer, an electroluminescent layer, i.e. a layer of a light-emitting material, in particular a light-emitting polymer, and an electrode (cathode) comprising a metal, preferably a metal with a low work function. A structure of this kind is normally applied to a substrate, usually glass. The generated light reaches the observer through the substrate. An OLED with a light-emitting polymer in the electroluminescent layer is also designated a polyLED or PLED.

The curve of the brightness as a function of the applied voltage of all organic LEDs is characterized by a threshold voltage, above which luminescence is observed, and a subsequent, very steep linear increase in brightness.

The threshold voltage lies approximately in the range from 3 to 8 V. Above the threshold voltage, the brightness increases by approximately a factor of 4 when the applied voltage is increased by 1 V.

Efficient OLEDs are characterized by a low threshold voltage, and are operated at low voltages from 2 to 8 V.

In order to guarantee a uniform brightness over the emitting surface, the voltage drop over the cathode and anode must not be too great. In addition to a reduced brightness, the voltage drop also leads to a reduction in the efficiency of the OLED.

The voltage drop U over an electrode of an electroluminescent device is described in good approximation by the following equation:

$$U = \frac{ρ d I}{{F}_{E}} {F}_{EL}$$

ρ=specific resistance of the electrode
d=width of the electrode
I=current density
F_{E}=cross-sectional area of the electrode
F_{EL}=area of the electroluminescent device.

The voltage drop over a 100 nm thick electrode comprising SnO₂:In (ITO) with a specific resistance ρ of 10⁻⁴ Ω·cm and a current density I of 2 mA·cm⁻² is:

$$U = \frac{{10}^{- 4} Ωcm \cdot 2 m A \cdot {10}^{5}}{{cm}^{2} \cdot cm} {d}^{2} = \frac{20 mV}{{cm}^{2}} {d}^{2}$$

With, for example, an efficiency of approximately 30 lm·W⁻¹ and an emitted light flux of approximately 3000 lumen, a current density I of 2 mA·cm⁻² is reached at an operating voltage of 5 V.

The brightness of a 10 cm wide light source thus declines by more than a factor of 5 over the width. With a 10 cm×10 cm area, which is contacted all round the edges, the brightness declines from the edge towards the center by more than a factor of 5.

The specific resistance of the electrode comprising ITO may be reduced only linearly with the increasing of the layer thickness. However, this leads to increased manufacturing costs and a reduced visual transmission of the electrode. Although metals have a considerably smaller specific resistance than ITO, in order to achieve a sufficient visual transparency the layer thicknesses of metallic electrodes have to be so thin that no appreciable advantage is achieved as a result.

It is therefore an object of the present invention to provide an electroluminescent device equipped with a homogeneous brightness over the entire electroluminescent device.

This object is achieved by an electroluminescent device equipped with a substrate, a metallic structure and a layer assembly comprising at least a first electrode, an electroluminescent layer and a second electrode, wherein the metallic structure is in electrical contact with the first electrode, and the layer resistance of the metallic structure is lower than the layer resistance of the first electrode.

Owing to the electrical contact of the metallic structure with the first transparent electrode, the layer resistance of the first transparent electrode, and thus the voltage drop over the first transparent electrode, is reduced.

Using the advantageous embodiment as claimed in claim 2, the advantageous electroluminescent device may be obtained in a simple, cost-effective manner, without the manufacturing process having to be expanded with deposition and structuring steps. Furthermore, this embodiment is advantageous in the case of electroluminescent devices with thin layers.

Using the advantageous embodiment as claimed in claim 3, the layer resistance of the first electrode may be reduced particularly effectively.

Owing to the advantageous embodiment as claimed in claim 4, the proportional area of the metal is small compared with the overall area of the substrate, so reflection losses are low and the emission of the light is homogeneous.

Using the advantageous embodiment as claimed in claim 5, the pattern of the metallic structure may be matched to existing structures within the layer assembly.

The invention will be further described with reference to examples of embodiments shown in the drawings, to which, however, the invention is not restricted.

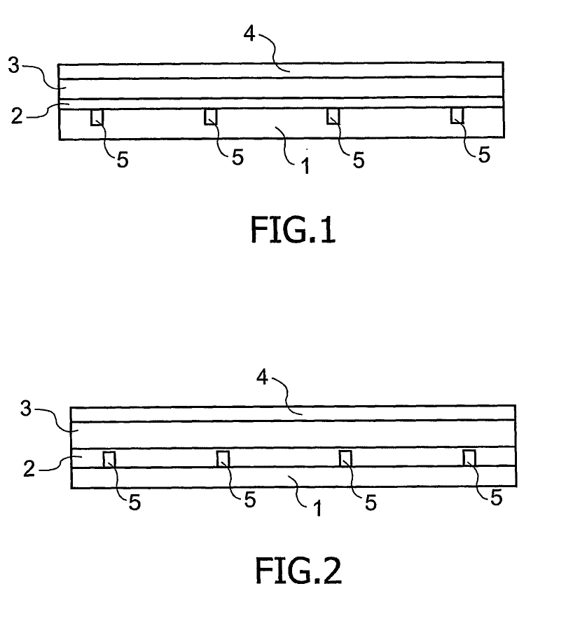

FIG. 1 shows, in cross-section, an electroluminescent device in accordance with the invention.

FIG. 2 shows, in cross-section, a further electroluminescent device in accordance with the invention.

In accordance with FIG. 1, an electroluminescent device is equipped with a substrate 1, preferably a transparent glass panel or a transparent plastic panel. The plastic panel may comprise, for example, polyethylene terephthalate (PET). Adjoining the substrate 1 is a layer assembly comprising at least a first electrode 2, an electroluminescent layer 3 and a second electrode 4. The first electrode 2 acts as the anode and the second electrode 4 acts as the cathode.

The first electrode 2 is preferably transparent, and may, for example, comprise p-doped silicon, indium-doped tin oxide (ITO) or antimony-doped tin oxide (ATO). Preferably, the first electrode 2 comprises ITO. The first electrode 2 is not structured, but rather is executed as a flat surface. The second electrode 4 may, for example, comprise a metal such as aluminum, copper, silver or gold, an alloy or n-doped silicon. It may be preferred that the second electrode 4 is equipped with two or more conductive layers. It may, in particular, be preferred that the second electrode 4 comprises a first layer comprising an alkaline earth metal, such as calcium or barium, and a second layer comprising aluminum. The second electrode 4 is preferably structured and equipped with a plurality of parallel strips comprising the conductive material or conductive materials. Alternatively, the second electrode 4 may be unstructured and executed as a flat surface.

The electroluminescent layer 3 may comprise a light-emitting polymer or small, organic molecules. Depending on the type of material used in the electroluminescent layer 3, the device is designated an LEP (Light Emitting Polymer) or a polyLED or smOLED (Small Molecule Organic Light Emitting Diode). Preferably, the electroluminescent layer 3 comprises a light-emitting polymer. Examples of materials that may be used as light-emitting polymers are poly(p-phenylvinylene) (PPV) or a substituted PPV, such as dialkoxy-substituted PPV.

When an appropriate voltage, typically of a few volts, is applied to the electrodes 2, 4, positive and negative charge carriers are injected, and these migrate to the electroluminescent layer 3, where they recombine and thereby generate light. This light travels through the first electrode 2 and the substrate 1 to the observer. If the electroluminescent layer 3 is doped with fluorescing pigments, the light generated by an electron hole recombination excites the pigments, which in turn emit light, for instance in one of three primary colors.

Alternatively, the layer assembly may be equipped with additional layers, such as a hole transporting layer and/or an electron transporting layer. A hole transporting layer is arranged between the first electrode 2 and the electroluminescent layer 3. An electron transporting layer is located between the second electrode 4 and the electroluminescent layer 3. Both layers preferably comprise conductive polymers. A hole transporting layer may, for example, comprise a mixture of polyethylene dioxythiophene (PDOT) and poly(styrene sulfonate).

Preferably incorporated into the substrate 1 is a metallic structure 5, comprising, for example, aluminum, copper, silver or gold or an alloy. The metallic structure 5 may, for example, comprise strips, in particular parallel strips. The distance between the individual strips may be, but does not have to be, constant. Alternatively, the metallic structure 5 may be a grid comprising a plurality of strips, arranged to be perpendicular in relation to each other. The metallic structure 5 may also comprise parallel wavy lines, zigzag lines, sawtooth lines or similar patterns. The pattern of the metallic structure 5 may thereby also be matched to existing patterns in the layer structure of the layer assembly.

In order to produce a metallic structure 5 in a substrate 1 comprising glass, a grid comprising a metallic wire may be rolled into the still liquid glass. Alternatively, just individual metallic wires may also be rolled into the liquid glass.

A further option for manufacturing a metallic structure 5 in a substrate 1 comprising glass comprises the generation, using known methods, of grooves in the substrate 1 comprising glass, and filling these grooves with a metal or an alloy. An example of a suitable method of manufacturing the grooves is sand blasting. The filling of the grooves may take place by, for example, vapor deposition methods, screen printing of conductive metal pastes or by photolithographic methods.

Alternatively, as shown in FIG. 2, the metallic structure 5 may be applied to the substrate 1. This may be done by, for example, vapor deposition methods, screen printing of conductive metal pastes or by photolithographic methods.

In both cases, it is preferred that the metallic structure covers not more than 10% of the surface of the substrate 1. In the event that the metallic structure 5 is located in the substrate 1, covering means that the surface of the substrate that adjoins the first electrode 2 comprises up to 10% of the metallic structure.

Metals have a lower specific resistance than ITO. For example, the specific resistance ρ of ITO is 10⁻⁴ Ω·cm, the specific resistance ρ of Al is 0.027·10⁻⁴ Ω·cm and the specific resistance ρ of Ag is 0.016·10⁻⁴ Ω·cm. However, the layer resistance of a metallic layer also depends on the layer thickness, so the layer resistance of a thicker layer is lower than in the case of a thinner layer comprising the same conductive material.

Owing to the electrical contact of the metallic structure 5 with a lower layer resistance than the first electrode, the layer resistance of the first electrode 2 is reduced overall.

So, using a metallic structure 5 comprising Ag strips with a thickness of 16 μm, with a surface covering of the metallic structure 5 of one percent, the layer resistance of a 160 nm thick layer comprising ITO may be reduced by a factor of 100.

Owing to the reduced layer resistance, the voltage drop over the area of the first electrode 2 is considerably reduced. The electroluminescent device exhibits a homogeneous light emission.

### EMBODIMENT EXAMPLE 1

A 356 mm×356 mm glass substrate 1 is coated with a photosensitive layer of polyurethane. The polyurethane layer was exposed and structured in such a way that the polyurethane was removed in strips over a width of 200 μm spaced at 20 mm.

Subsequently, glass was removed by sandblasting in the areas not covered with polyurethane. The depth of the grooves was 350 μm.

Once the remaining areas of the polyurethane layer had been removed, the grooves in the substrate 1 comprising glass were filled with a conductive silver paste by multiple screen printing operations.

The layers of the layer assembly, such as the first electrode 2 comprising ITO, a hole transporting layer comprising polyethylene dioxythiophene (PDOT) and poly(styrene sulfonate), an electroluminescent layer 3 comprising PPV and a second, unstructured electrode 4 comprising a first, 5 nm thick layer with barium and a second, 200 nm thick layer of aluminum, were then applied using known methods.

An electroluminescent device with improved homogeneity of light emission was obtained.

### EMBODIMENT EXAMPLE 2

A Cu wire grid with individual wires with a layer thickness of 400 μm and a width of 200 μm was rolled into a still liquid glass substrate 1. The distance between the individual wires was 25 mm.

Following cooling and solidification of the glass substrate 1, the further layers were applied by analogy with embodiment example 1.

An electroluminescent device with improved homogeneity of light emission was obtained.

1. An electroluminescent device equipped with a substrate (1), a metallic structure (5) and a layer assembly comprising at least a first electrode (2), an electroluminescent layer (3) and a second electrode (4), wherein the metallic structure (5) is in electrical contact with the first electrode (2), and the layer resistance of the metallic structure (5) is lower than the layer resistance of the first electrode (2).

2. An electroluminescent device as claimed in claim 1, characterized in that the metallic structure (5) is incorporated into the substrate (1).

3. An electroluminescent device as claimed in claim 1, characterized in that the layer thickness of the metallic structure (5) is greater than the layer thickness of the first electrode (2).

4. An electroluminescent device as claimed in claim 1, characterized in that the metallic structure (5) covers up to 10% of the surface of the substrate.

5. An electroluminescent device as claimed in claim 1, characterized in that the metallic structure (5) exhibits a structure selected from the group of strips, grids, wavy lines, zigzag lines and sawtooth lines.
